(19) United States
(12) Patent Application Publication
(10) Pub. No.: US 2014/0026935 A1
(43) Pub. Date: Jan. 30, 2014

(54) METHOD FOR MANUFACTURING ARRAY SUBSTRATE WITH EMBEDDED PHOTOVOLTAIC CELL AND ARRAY SUBSTRATE MANUFACTURED WITH SAME

(71) Applicant: Xindi Zhang, Shenzhen (CN)

(72) Inventor: Xindi Zhang, Shenzhen (CN)

(73) Assignee: SHENZHEN CHINA STAR OPTOELECTRONICS TECHNOLOGY CO., LTD., Shenzhen, Guangdong (CN)

(21) Appl. No.: 13/698,084

(22) PCT Filed: Aug. 10, 2012
(86) PCT No.: PCT/CN2012/079903

§ 371 Date: Nov. 15, 2012

(30) Foreign Application Priority Data
Jul. 27, 2012 (CN) 201210264249.4

(51) Int. Cl. H01L 27/32

(52) U.S. Cl. CPC H01L 27/3227
USPC 136/244; 438/73

(57) ABSTRACT

The present invention provides a method for manufacturing array substrate with embedded photovoltaic cell and an array substrate manufactured with same. The method includes: (1) providing a substrate; (2) forming a transparent conductive layer on the substrate; (3) forming a conductivity enhancing layer on the transparent conductive layer; (4) forming a photovoltaic layer on the conductivity enhancing layer; (5) forming a metal layer on the photovoltaic layer; (6) applying a masking process to form an opening in the metal layer, the photovoltaic layer, the conductivity enhancing layer, and the transparent conductive layer; (7) forming a transparent insulation layer on the metal layer; and (8) forming a TFT array on the transparent insulation layer. The present invention allows a photovoltaic cell to be embedded in an array substrate through a simple process and allows a full use of the photo energy from a backlight module.

### BACKGROUND OF THE INVENTION

1. Field of the Invention

The present invention relates to the field of liquid crystal displaying, and in particular to a method for manufacturing array substrate with embedded photovoltaic cell and an array substrate manufactured with the same.

2. The Related Arts

Liquid crystal display (LCD) has a variety of advantages, such as thin device body, low power consumption, and being free of radiation, and is thus widely used. Most of the LCDs that are currently available in the market are backlighting LCDs, which comprise a liquid crystal display panel and a backlight module. The operation principle of the liquid crystal display panel is that liquid crystal molecules are interposed between two parallel glass substrates and the liquid crystal molecules are controlled to change direction by application of electricity to the glass substrates in order to refract light emitting from the backlight module for generating images. Since the liquid crystal display panel itself does not emit light, light must be provided by the backlight module in order to normally display images. Thus, the backlight module is one of the key components of an LCD. The backlight module can be classified in two types, namely side-edge backlight module and direct backlight module, according to the position where light gets incident. The direct backlight module arranges a light source, such as a cold cathode fluorescent lamp (CCFL) or a light-emitting diode (LED), at the back side of the liquid crystal display panel to form a planar light source that directly provides lighting to the liquid crystal display panel. The side-edge backlight module arranges a backlight source of LED light bar at an edge of a back panel to be located rearward of one side of the liquid crystal display panel. The LED light bar emits light that enters a light guide plate (LGP) through a light incident face of the light guide plate and is projected out through a light emergence face of the light guide plate, after being reflected and diffused, to thereby transmit through an optic film assembly and form a planar light source for the liquid crystal display panel. However, there is only about 6% of the light emitting from the backlight source that can transmit through the liquid crystal display panel. This cause a waste of a large amount of light energy.

A liquid crystal display panel is generally composed of a color filter (CF) substrate, a thin film transistor (TFT) substrate, and liquid crystal (LC) and sealant interposed between the CF substrate and the TFT substrate. A general manufacturing process comprises a front stage of array process (including thin film, yellow light, etching, and film stripping), an intermediate stage of cell process (including bonding TFT substrate and CF substrate), and a rear stage of assembling process (including mounting drive ICs and printed circuit board). The front stage of array process generally makes the TFT substrate for controlling the movement of liquid crystal molecules. The intermediate stage of cell process generally introduces the liquid crystal between the TFT substrate and the CF substrate. The rear stage of assembling process generally mounts the drive ICs and combining the printed circuit board to effect driving the liquid crystal molecules to rotate for displaying images.

The current TFT substrate comprises first and second metal electrodes that shield the light of the backlight module to some extents, preventing the light from the backlight module from being completely used by a liquid crystal display panel and thus causing a loss of photo energy.

A photovoltaic cell is a device that directly converts photo energy into electrical energy through photoelectrical effect or photochemical effect. To improve the utilization of light from the backlight module of a liquid crystal display device, those skilled in the art include photovoltaic cells in the liquid crystal display panel. The photovoltaic cells absorb excessive photo energy and convert the photo energy into electrical energy to power components or accessories of the liquid crystal display panel. Photo energy emitting from the backlight source can thus be fully used and the consumption of external power sources can be reduced.

However, the current manufacturing techniques only work to integrate already-manufactured photovoltaic cells with the liquid crystal display panel. The manufacturing process is complicated and the manufacture cycle is long, so that the manufacture cost is increased.

### SUMMARY OF THE INVENTION

An object of the present invention is to provide a method for manufacturing an array substrate with embedded photovoltaic cell, which first forms a photovoltaic cell on a substrate and then forms a TFT array on the photovoltaic cell so as to effectively use the photo energy of a backlight module, reduce the consumption of an external power source, and lower down manufacture cost.

Another object of the present invention is to provide an array substrate with embedded photovoltaic cell, which effectively uses the photo energy of a backlight module, reduces the consumption of an external power source, and lowers down manufacture cost.

To achieve the objects, the present invention provides a method for manufacturing an array substrate with embedded photovoltaic cell, which comprises the following steps:

Step 1: providing a substrate;

Step 2: forming a transparent conductive layer on the substrate;

Step 3: forming a conductivity enhancing layer on the transparent conductive layer;

Step 4: forming a photovoltaic layer on the conductivity enhancing layer;

Step 5: forming a metal layer on the photovoltaic layer;

Step 6: applying a masking process to form an opening in the metal layer, the photovoltaic layer, the conductivity enhancing layer, and the transparent conductive layer;

Step 7: forming a transparent insulation layer on the metal layer; and

Step 8: forming a TFT array on the transparent insulation layer.

The substrate comprises a glass substrate.

The transparent conductive layer comprises an indium-tin oxide, which is formed on the substrate through a sputtering operation.

The conductivity enhancing layer comprises a polymer layer of 3,4-ethylenedioxythiophene, which is formed on the transparent conductive layer through coating.

The photovoltaic layer comprises an organic polymer photovoltaic layer, a small molecular organic photovoltaic layer, or a P-N junction photovoltaic layer, which is formed on the conductivity enhancing layer through coating.

The metal layer comprises an aluminum layer, which is formed on the photovoltaic layer through a sputtering operation.

The masking process comprises exposure, development, and etching operations.

The transparent insulation layer comprises a silicon nitride layer, which is formed on the metal layer through coating.

The present invention also provides a method for manufacturing array substrate with embedded photovoltaic cell, which comprises the following steps:

Step 1: providing a substrate;

Step 2: forming a transparent conductive layer on the substrate;

Step 3: forming a conductivity enhancing layer on the transparent conductive layer;

Step 4: forming a photovoltaic layer on the conductivity enhancing layer;

Step 5: forming a metal layer on the photovoltaic layer;

Step 6: applying a masking process to form an opening in the metal layer, the photovoltaic layer, the conductivity enhancing layer, and the transparent conductive layer;

Step 7: forming a transparent insulation layer on the metal layer; and

Step 8: forming a TFT array on the transparent insulation layer;

wherein the substrate comprises a glass substrate;

wherein the transparent conductive layer comprises an indium-tin oxide, which is formed on the substrate through a sputtering operation;

wherein the conductivity enhancing layer comprises a polymer layer of 3,4-ethylenedioxythiophene, which is formed on the transparent conductive layer through coating;

wherein the photovoltaic layer comprises an organic polymer photovoltaic layer, a small molecular organic photovoltaic layer, or a P-N junction photovoltaic layer, which is formed on the conductivity enhancing layer through coating;

wherein the metal layer comprises an aluminum layer, which is formed on the photovoltaic layer through a sputtering operation;

wherein the masking process comprises exposure, development, and etching operations; and

wherein the transparent insulation layer comprises a silicon nitride layer, which is formed on the metal layer through coating.

The present invention also provides an array substrate with embedded photovoltaic cell, which comprises a substrate, a photovoltaic cell formed on the substrate, a TFT array formed on the photovoltaic cell, and a transparent insulation layer formed between the photovoltaic cell and the TFT array. The photovoltaic cell comprises a transparent conductive layer, a conductivity enhancing layer formed on the transparent conductive layer, a photovoltaic layer formed on the conductivity enhancing layer, and a metal layer formed on the photovoltaic layer.

The substrate comprises a glass substrate. The transparent conductive layer comprises an indium-tin oxide layer. The conductivity enhancing layer comprises a polymer layer of 3,4-ethylenedioxythiophene. The photovoltaic layer comprises an organic polymer photovoltaic layer, a small molecular organic photovoltaic layer, or a P-N junction photovoltaic layer. The metal layer comprises an aluminum layer. The transparent insulation layer comprises a silicon nitride layer.

The efficacy of the present invention is that the present invention provides a method for manufacturing an array substrate with embedded photovoltaic cell and an array substrate manufactured with same, which form a photovoltaic cell on a substrate and then forms a TFT array on the photovoltaic cell so as to have the photovoltaic cell embedded in the array substrate with a simple process thereby allowing the components or accessories of a liquid crystal display panel to be energized with light emitting from a backlight module for making a full use of the photo energy emitting from the backlight module and reducing consumption of external electrical power.

For better understanding of the features and technical contents of the present invention, reference will be made to the following detailed description of the present invention and the attached drawings. However, the drawings are provided for the purposes of reference and illustration and are not intended to impose undue limitations to the present invention.

### BRIEF DESCRIPTION OF THE DRAWINGS

The technical solution, as well as beneficial advantages, will be apparent from the following detailed description of an embodiment of the present invention, with reference to the attached drawings. In the drawings:

FIG. 1 is a flow chart illustrating a method for manufacturing an array substrate with embedded photovoltaic cell according to the present invention; and

FIG. 2 is a schematic view showing the structure of an array substrate with embedded photovoltaic cell according to the present invention.

### DETAILED DESCRIPTION OF THE PREFERRED EMBODIMENTS

To further expound the technical solution adopted in the present invention and the advantages thereof, a detailed description is given to a preferred embodiment of the present invention and the attached drawings.

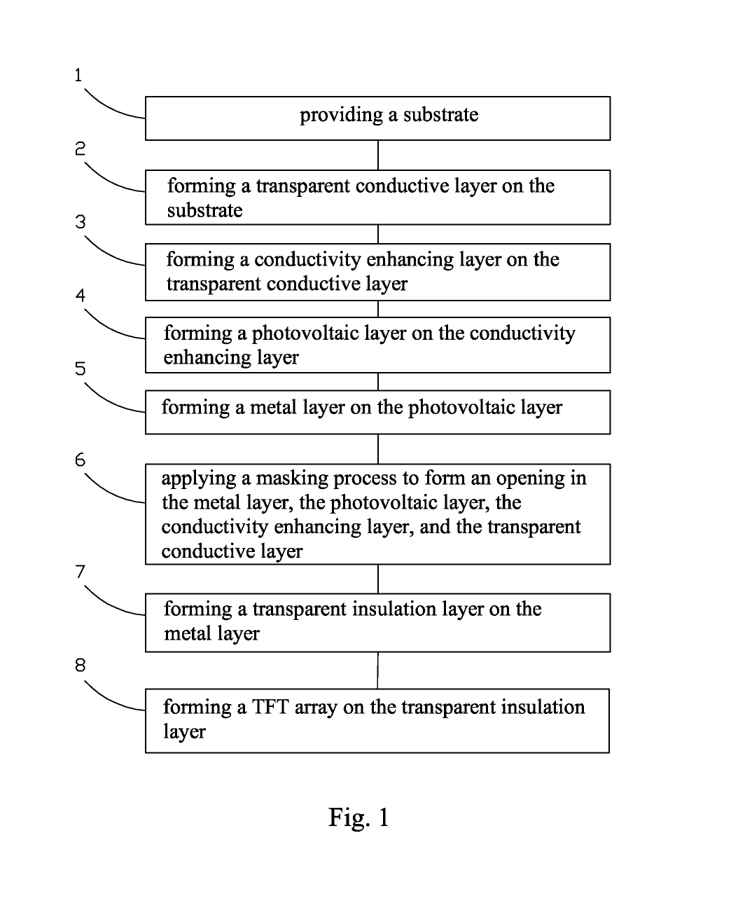

Referring to FIG. 1, the present invention provides a method for manufacturing an array substrate with embedded photovoltaic cell, which comprises the following steps:

Step 1: providing a substrate, wherein the substrate is made of a light-transmitting material and is generally a glass substrate, a quartz substrate, or a substrate made of any other suitable materials.

Step 2: forming a transparent conductive layer on the substrate.

The transparent conductive layer comprises an indium-tin oxide (ITO) layer. The transparent conductive layer is formed on the substrate through a sputtering process.

Step 3: forming a conductivity enhancing layer on the transparent conductive layer.

The conductivity enhancing layer comprises a polymer (PEDOT) layer of 3,4-ethylenedioxythiophene (EDOT), which is formed on the transparent conductive layer through coating in order to enhance the conducting power of holes.

Step 4: forming a photovoltaic layer on the conductivity enhancing layer.

The photovoltaic layer comprises an organic polymer photovoltaic layer, a small molecular organic photovoltaic layer, or a P-N junction photovoltaic layer, which is formed on the conductivity enhancing layer through coating to absorb photo energy, serving as a photovoltaic absorption layer for an array substrate with embedded photovoltaic cell according to the present invention.

Preferably, the photovoltaic layer comprises a Fullerene material layer, a dye-sensitized material layer, or a polystyrene material layer.

Step 5: forming a metal layer on the photovoltaic layer.

The metal layer comprises an aluminum (Al) layer, which is formed on the photovoltaic layer through a sputtering process to serve as electrode material for anode of the photovoltaic cell.

Step 6: applying a masking process to form an opening in the metal layer, the photovoltaic layer, the conductivity enhancing layer, and the transparent conductive layer.

The opening is the site of a pixel aperture so as not to affect the aperture ratio of the panel.

The masking process comprises exposure, development, and etching operations. This process can be replaced by a dry etching process that similarly achieves the technical result of the present invention.

Step 7: forming a transparent insulation layer on the metal layer.

The transparent insulation layer comprises a silicon nitride layer, which is formed on the metal layer through coating in order to effect insulative isolation of the metal layer from the TFT layer and to provide an effect of planarization of substrate to reduce the influence of the manufacture of photovoltaic component on the TFT array.

Step 8: forming a TFT array on the transparent insulation layer.

The TFT array can be formed with any known techniques, which can realize the technical result of the present invention. Repeated description of this step will be omitted.

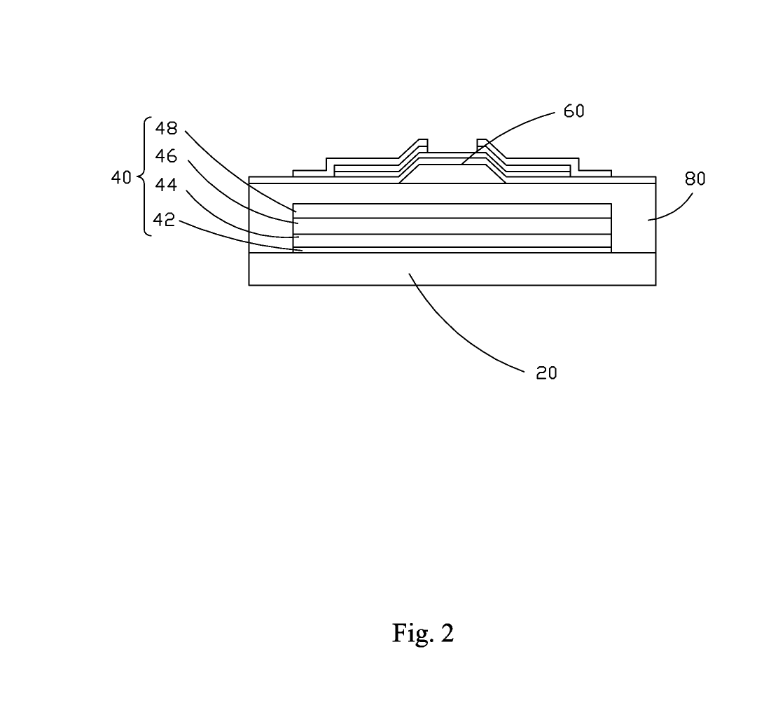

Referring to FIG. 2, the present invention also provides an array substrate with embedded photovoltaic cell, which comprises a substrate 20, a photovoltaic cell 40 formed on the substrate 20, a TFT array 60 formed on the photovoltaic cell 40, and a transparent insulation layer 80 formed between the photovoltaic cell 40 and the TFT array 60.

The photovoltaic cell 40 comprises a transparent conductive layer 42, a conductivity enhancing layer 44 formed on the transparent conductive layer 42, a photovoltaic layer 46 formed on the conductivity enhancing layer 44, and a metal layer 48 formed on the photovoltaic layer 46.

In the instant embodiment, the substrate 20 is a glass substrate. The transparent insulation layer 80 is a silicon nitride layer to effect insulative isolation between the photovoltaic cell 40 and the TFT array 60.

The transparent conductive layer 42 is an indium-tin oxide layer. The conductivity enhancing layer 44 is a polymer layer of 3,4-ethylenedioxythiophene to enhance the conducting power of holes. The photovoltaic layer 46 is an organic polymer photovoltaic layer, a small molecular organic photovoltaic layer, or a P-N junction photovoltaic layer for absorbing photo energy. The metal layer 48 is an aluminum layer to serve as an electrode material for anode of the photovoltaic cell.

In summary, the present invention provides a method for manufacturing an array substrate with embedded photovoltaic cell and an array substrate manufactured with same, which form a photovoltaic cell on a substrate and then forms a TFT array on the photovoltaic cell so as to have the photovoltaic cell embedded in the array substrate with a simple process thereby allowing the components or accessories of a liquid crystal display panel to be energized with light emitting from a backlight module for making a full use of the photo energy emitting from the backlight module and reducing consumption of external electrical power.

Based on the description given above, those having ordinary skills of the art may easily contemplate various changes and modifications of the technical solution and technical ideas of the present invention and all these changes and modifications are considered within the protection scope of right for the present invention.

What is claimed is:

1. A method for manufacturing array substrate with embedded photovoltaic cell, comprising the following steps:
(1) providing a substrate;
(2) forming a transparent conductive layer on the substrate;
(3) forming a conductivity enhancing layer on the transparent conductive layer;
(4) forming a photovoltaic layer on the conductivity enhancing layer;
(5) forming a metal layer on the photovoltaic layer;
(6) applying a masking process to form an opening in the metal layer, the photovoltaic layer, the conductivity enhancing layer, and the transparent conductive layer;
(7) forming a transparent insulation layer on the metal layer; and
(8) forming a TFT array on the transparent insulation layer.

2. The method for manufacturing array substrate with embedded photovoltaic cell as claimed in claim 1, wherein the substrate comprises a glass substrate.

3. The method for manufacturing array substrate with embedded photovoltaic cell as claimed in claim 1, wherein the transparent conductive layer comprises an indium-tin oxide, which is formed on the substrate through a sputtering operation.

4. The method for manufacturing array substrate with embedded photovoltaic cell as claimed in claim 1, wherein the conductivity enhancing layer comprises a polymer layer of 3,4-ethylenedioxythiophene, which is formed on the transparent conductive layer through coating.

5. The method for manufacturing array substrate with embedded photovoltaic cell as claimed in claim 1, wherein the photovoltaic layer comprises an organic polymer photovoltaic layer, a small molecular organic photovoltaic layer, or a P-N junction photovoltaic layer, which is formed on the conductivity enhancing layer through coating.

6. The method for manufacturing array substrate with embedded photovoltaic cell as claimed in claim 1, wherein the metal layer comprises an aluminum layer, which is formed on the photovoltaic layer through a sputtering operation.

7. The method for manufacturing array substrate with embedded photovoltaic cell as claimed in claim 1, wherein the masking process comprises exposure, development, and etching operations.

8. The method for manufacturing array substrate with embedded photovoltaic cell as claimed in claim 1, wherein the transparent insulation layer comprises a silicon nitride layer, which is formed on the metal layer through coating.

9. A method for manufacturing array substrate with embedded photovoltaic cell, comprising the following steps:
(1) providing a substrate;
(2) forming a transparent conductive layer on the substrate;
(3) forming a conductivity enhancing layer on the transparent conductive layer;
(4) forming a photovoltaic layer on the conductivity enhancing layer;
(5) forming a metal layer on the photovoltaic layer;
(6) applying a masking process to form an opening in the metal layer, the photovoltaic layer, the conductivity enhancing layer, and the transparent conductive layer;
(7) forming a transparent insulation layer on the metal layer; and
(8) forming a TFT array on the transparent insulation layer;
wherein the substrate comprises a glass substrate;
wherein the transparent conductive layer comprises an indium-tin oxide, which is formed on the substrate through a sputtering operation;
wherein the conductivity enhancing layer comprises a polymer layer of 3,4-ethylenedioxythiophene, which is formed on the transparent conductive layer through coating;
wherein the photovoltaic layer comprises an organic polymer photovoltaic layer, a small molecular organic photovoltaic layer, or a P-N junction photovoltaic layer, which is formed on the conductivity enhancing layer through coating;
wherein the metal layer comprises an aluminum layer, which is formed on the photovoltaic layer through a sputtering operation;
wherein the masking process comprises exposure, development, and etching operations; and
wherein the transparent insulation layer comprises a silicon nitride layer, which is formed on the metal layer through coating.

10. An array substrate with embedded photovoltaic cell, comprising a substrate, a photovoltaic cell formed on the substrate, a TFT array formed on the photovoltaic cell, and a transparent insulation layer formed between the photovoltaic cell and the TFT array, the photovoltaic cell comprising a transparent conductive layer, a conductivity enhancing layer formed on the transparent conductive layer, a photovoltaic layer formed on the conductivity enhancing layer, and a metal layer formed on the photovoltaic layer.

11. The array substrate with embedded photovoltaic cell as claimed in claim 10, wherein the substrate comprises a glass substrate, the transparent conductive layer comprising an indium-tin oxide layer, the conductivity enhancing layer comprising a polymer layer of 3,4-ethylenedioxythiophene, the photovoltaic layer comprising an organic polymer photovoltaic layer, a small molecular organic photovoltaic layer, or a P-N junction photovoltaic layer, the metal layer comprising an aluminum layer, the transparent insulation layer comprising a silicon nitride layer.
